(19) United States
(12) Patent Application Publication
(10) Pub. No.: US 2011/0126907 A1
(43) Pub. Date: Jun. 2, 2011

(54) SOLAR CELL AND METHOD OF MANUFACTURING THE SAME

(75) Inventors: Jin-Wook LEE, Suwon-si (KR); Doo-Youl LEE, Seoul (KR); Hwa-Young KO, Seoul (KR)

(73) Assignee: SAMSUNG ELECTRONICS CO., LTD., Suwon-si (KR)

(21) Appl. No.: 12/819,346

(22) Filed: Jun. 21, 2010

(30) Foreign Application Priority Data
Dec. 2, 2009 (KR) 10-2009-0118558

(51) Int. Cl. H01L 31/00; H01L 31/18

(52) U.S. Cl. 136/261; 438/87; 257/E31.037

(57) ABSTRACT

A solar cell includes; a semiconductor substrate, an n+ region disposed on a surface of the semiconductor substrate, a plurality of first electrodes connected to the n+ region, a p+ region disposed on the surface of the semiconductor substrate and separated from the n+ region, a second electrode connected to the p+ region, and a first dielectric layer which has a positive fixed charge and is disposed between adjacent first electrodes of the plurality of first electrodes, and a method of manufacturing the same.

### CROSS-REFERENCE TO RELATED APPLICATION

This application claims priority to Korean Patent Application No. 10-2009-0118558, filed on Dec. 2, 2009, and all the benefits accruing therefrom under 35 U.S.C. §119, the content of which in its entirety is herein incorporated by reference.

### BACKGROUND

1. Field

This disclosure relates to a solar cell and a method of manufacturing the same.

2. Description of the Related Art

A solar cell is a photoelectric conversion device that transforms photonic energy, typically solar energy, into electrical energy, and has attracted much attention as a renewable and pollution-free next generation energy source.

A typical solar cell includes p-type and n-type semiconductors and produces electrical energy by transferring electrons and holes to the n-type and p-type semiconductors, respectively, and then collecting electrons and holes in each electrode when an electron-hole pair (“EHP”) is produced by solar light energy absorbed in a photoactive layer inside the semiconductors.

Further, it is desirable that a solar cell have as much efficiency as possible for producing electrical energy from solar energy. In order to increase the efficiency of a solar cell, efforts have been made to produce as many electron-hole pairs as possible in a semiconductor, and efforts have been made to withdraw a resultant charge with minimal loss.

Research on improvement of generation efficiency of electron-hole pairs and on reducing recombination of generated electrons and holes resulting in improvement in efficiency of a solar cell have been actively made.

### SUMMARY

One aspect of this disclosure provides a solar cell having high efficiency, and a method of manufacturing the same.

According to one embodiment of this disclosure, a solar cell includes; a semiconductor substrate, an n+ region disposed on a surface of the semiconductor substrate. a plurality of first electrodes connected with the n+ region, a p+ region disposed on the surface of the semiconductor substrate and separated from the n+ region, a second electrode connected to the p+ region, and a first dielectric layer having a positive fixed charge disposed between adjacent first electrodes of the plurality of first electrodes.

In one embodiment, the n+ region and the p+ region may be alternately disposed.

In one embodiment, the first dielectric layer may include an oxide, a nitride, an oxynitride, or a combination thereof having a positive fixed charge, and may have a positive fixed charge density of about 1×10¹¹ cm⁻² to about 1×10¹³ cm⁻².

In one embodiment, the first dielectric layer may have a thickness of about 10 nm to about 200 nm.

In one embodiment, the solar cell may further include a second dielectric layer disposed on one surface of the semiconductor substrate and positioned on a region where the first electrode and the second electrode are omitted.

In one embodiment, the second dielectric layer may have a negative fixed charge. The second dielectric layer may include an oxide, a nitride, an oxynitride, or a combination thereof having a negative fixed charge and may have a negative fixed charge density of about −1×10¹⁰ cm⁻² to about −1×10¹³ cm⁻². The second dielectric layer may have a larger surface area than that of the first dielectric layer.

In one embodiment, the second dielectric layer may have a thickness of about 10 nm to about 200 nm, and the second dielectric layer may be removed in a region where it is overlapped with the first dielectric layer.

According to another embodiment of this disclosure, a method of manufacturing a solar cell is provided that includes; providing a semiconductor substrate, providing an n+ region on one surface of the semiconductor substrate, providing a first dielectric layer at an overlapping region with the n+ region, providing a plurality of first electrodes connected to the n+ region, and providing a p+ region separated from the n+ region and a second electrode connected to the p+ region on the surface of the semiconductor substrate. The first dielectric layer is positioned between adjacent first electrodes of the plurality of first electrodes.

In one embodiment, the n+ region and the p+ region may be alternately disposed.

In one embodiment, the method of manufacturing a solar cell may further include providing a second dielectric layer on the surface of the semiconductor substrate after providing the first dielectric layer. In addition, the method of manufacturing a solar cell may further include removing the second dielectric layer at a position overlapping the first dielectric layer.

Other aspects of this disclosure will be described in the following detailed description.

### BRIEF DESCRIPTION OF THE DRAWINGS

The above and other aspects, advantages and features of this disclosure will become more apparent by describing in further detail embodiments thereof with reference to the accompanying drawings, in which:

FIG. 1 is a rear-side view of an embodiment of a solar cell;

FIG. 2 is a cross-sectional view of the embodiment of a solar cell of FIG. 1 taken along line II-II; and

FIGS. 3A to 3G are cross-sectional views that sequentially show an embodiment of a process of manufacturing the embodiment of a solar cell.

### DETAILED DESCRIPTION

Embodiments now will be described more fully hereinafter with reference to the accompanying drawings, in which embodiments of the invention are shown. The embodiments may, however, be embodied in many different forms and should not be construed as limited to the embodiments set forth herein. Rather, these embodiments are provided so that this disclosure will be thorough and complete, and will fully convey the scope of the embodiments to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting thereof. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure.

Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the disclosure.

All methods described herein can be performed in a suitable order unless otherwise indicated herein or otherwise clearly contradicted by context. The use of any and all examples, or exemplary language (e.g., “such as”), is intended merely to better illustrate the disclosure and does not pose a limitation on the scope thereof unless otherwise claimed. No language in the specification should be construed as indicating any non-claimed element as essential to the practice of the embodiments as used herein.

Hereinafter, the embodiments will be described in detail with reference to the accompanying drawings.

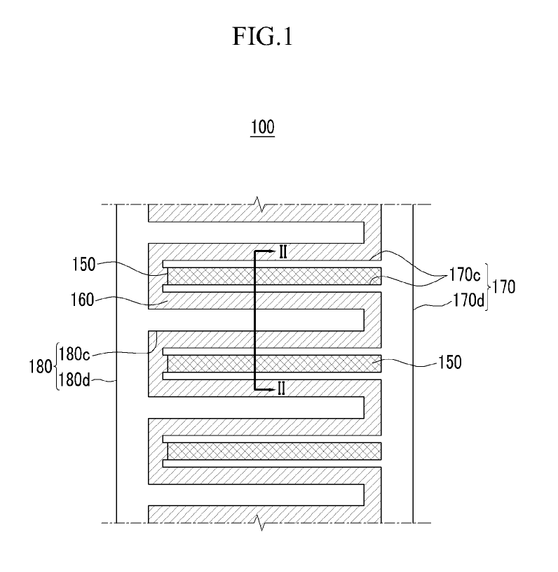

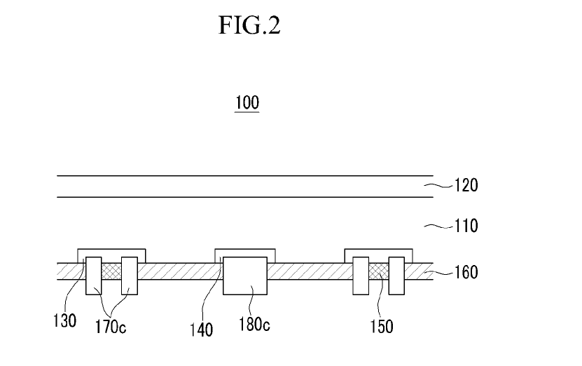

First, an embodiment of a solar cell according to this disclosure is described with reference to FIGS. 1 and 2.

FIG. 1 is a rear-side view of an embodiment of a solar cell 100.

As shown in FIG. 1, an n-type electrode 170 includes a plurality of first finger electrodes 170c contacting an upper and lower surface of a first dielectric layer 150, wherein upper and lower as shown from a plan view perspective are different than upper and lower as shown in a cross-sectional view, and a first bus bar electrode 170d connecting the first finger electrodes 170c. In addition, a p-type electrode 180 includes a second finger electrode 180c contacting a second dielectric layer 160, and a second bus bar electrode 180d connecting adjacent second finger electrodes 180c. In the present exemplary embodiment, the first dielectric layer 150 has a positive fixed charge. Although FIG. 1 shows an embodiment of a solar cell including the second dielectric layer 160, the disclosure is not limited thereto, and in alternative embodiments the second dielectric layer 160 may be omitted.

FIG. 2 is a cross-sectional view of the embodiment of a solar cell of FIG. 1 taken along line II-II.

Hereinafter, a side of a semiconductor substrate 110 that receives solar energy, e.g., the light source-facing side, is referred to as a front side, and the opposite side of the semiconductor substrate 110 is referred to as a rear side. For better understanding and ease of description, as used in the remainder of the application, the relationship between the upper and lower positions is described with reference to the center of the semiconductor substrate 110, but the present embodiments are not limited thereto.

The embodiment of a solar cell 100 includes: a semiconductor substrate 110; an n+ region 130 disposed on one surface of the semiconductor substrate 110; the plurality of first finger electrodes 170c connected to the n+ region 130; a p+ region 140 disposed on one surface of the semiconductor substrate 110 and separated from the n+ region 130; the second finger electrode 180c connecting to the p+ region 140; and the first dielectric layer 150 having a positive fixed charge and being disposed between adjacent first finger electrodes 170c. In one exemplary embodiment, the embodiment of a solar cell 100 also includes a second dielectric layer 160.

Embodiments of the semiconductor substrate 110 may be made of crystalline silicon, compound semiconductor or other similar materials. In the embodiment wherein the semiconductor substrate 110 is made of crystalline silicon, it may include, for example, a silicon wafer. The semiconductor substrate 110 may be doped with a p-type impurity or an n-type impurity. The p-type impurity may include a Group III compound, embodiments of which include boron (B), aluminum (Al), and other materials with similar characteristics, and the n-type impurity may include a Group V compound, embodiments of which include phosphorus (P) and other materials with similar characteristics.

In one embodiment, the semiconductor substrate 110 may have a textured front surface (not shown). The semiconductor substrate 110 with the textured front surface may have protrusions and depressions such as in a pyramid shape, or a porous structure such as a honeycomb structure. The semiconductor 110 with the textured front surface may increase light absorption and reduce reflectance by increasing a surface area of the front surface, resulting in increased efficiency of a solar cell 100.

Referring to FIG. 2, in the present embodiment an anti-reflection coating 120 is disposed on the front surface of the semiconductor substrate 110, but alternative embodiments include configurations wherein the anti-reflection coating 120 may be omitted. The anti-reflection coating 120 may be made of an insulating material that prevents a reflection of light therefrom, for example, it may an oxide such as aluminum oxide (Al₂O₃), silicon oxide (SiO₂), titanium oxide (TiO₂ or TiO₄), magnesium oxide (MgO), cerium oxide (CeO₂), other materials having similar characteristics or a combination thereof, a nitride such as aluminum nitride (AlN), silicon nitride (SiNₓ), titanium nitride (TiN), or other materials having similar characteristics or a combination thereof, an oxynitride such as aluminum oxynitride (AlON), silicon oxynitride (SiON), titanium oxynitride (TiON), or other materials having similar characteristics or a combination thereof. The anti-reflection coating 120 may be formed in a single layer or a plurality of layers.

In one embodiment, the anti-reflection coating 120 may have a thickness of about 5 nm to about 300 nm. In particular, in one embodiment the anti-reflection coating 120 may have a thickness of about 50 nm to about 80 nm.

The anti-reflection coating 120 is positioned on the front surface of the semiconductor substrate 110, and decreases the reflectance of light on the surface of the solar cell 100 and increases the selectivity of a certain wavelength region. That is, the anti-reflection coating 120 may at least partially control which wavelengths of light are absorbed in the solar cell 100 In addition, it is possible to increase the efficiency of the solar cell 100 by improving the contact characteristics with silicon present in the front surface of the semiconductor substrate 110.

In the present embodiment, the n+ region 130 and the p+ region 140 are disposed on the rear surface of the semiconductor substrate 110. The n+ region 130 and the p+ region 140 may be alternately disposed.

Since the n+ region 130 is doped with an n-type impurity, it is possible to easily collect the produced electrons into the electrode side, i.e., the n-type electrode 170.

In addition, since the p+ region 140 includes p-type impurities, it is possible to easily collect the produced holes into the electrode side, i.e., the p-type electrode 180. Although FIG. 2 shows that the p+ region 140 is separately provided, the solar cell 100 is not limited thereto, and the p+ region 140 may be formed while providing the second finger electrode 180c, so the additional providing of the p+ region 140 may be omitted.

A at least two of the first finger electrodes 170c are electrically connected under the n+ region 130, and the first dielectric layer 150 is disposed between at least two adjacent first finger electrodes 170c that are electrically connected under the n+ region 130.

The first finger electrodes 170c may carry out the role of collecting the produced electrons from the semiconductor substrate 110 and transporting them to an outside, e.g., a battery, a voltage load, etc. The finger electrodes 170c may be formed of a low resistance metal such as silver (Ag) or other materials with similar characteristics, but the solar cell 100 is not limited thereto.

The first finger electrodes 170c are connected to each other via the first bus bar electrode 170d, and the first bus bar electrode 170d may be formed of, for example, silver (Ag), aluminum (Al), or other materials with similar characteristics or a combination thereof.

The first dielectric layer 150 has a positive fixed charge. Because the first dielectric layer 150 has a positive fixed charge, the electrons produced from the semiconductor substrate 110 are drawn to the n+ region 130 side. Thereby, it is possible to effectively collect electrons into the first finger electrode 170c and improve the efficiency of the solar cell 100.

The material having a positive fixed charge that may be included in the first dielectric layer 150 may include an oxide, a nitride, an oxynitride, other materials having similar characteristics or a combination thereof having a predetermined composition, but the first dielectric layer 150 is not limited thereto. A nitride such as SiₓN_{y} may have a positive fixed charge by adjusting the ratio of x and y. For example, in one embodiment the nitride may have a positive fixed charge when x<y. In the same way, a material such as AlₓO_{y}, SiₓO_{y}, SiₓO_{y}N_{z}, or the like may have a positive fixed charge by adjusting the ratio of x, y, and z. According to one embodiment, the material having a positive fixed charge that may be included in the first dielectric layer 150 may include silicon nitride (Si₃N₄), oxidation zirconium (ZrO₂), or other materials with similar characteristics.

In one embodiment, the first dielectric layer 150 may have a positive fixed charge density of about 1×10¹¹ cm⁻² to about 1×10¹³ cm⁻². When the first dielectric layer 150 has a positive fixed charge density within the above-described range, it may easily draw the produced electrons from the semiconductor substrate 110 into the n+ region 130 side, so as to effectively improve the efficiency of the solar cell 100.

The first dielectric layer 150 may have a thickness of about 10 nm to about 200 nm. When the first dielectric layer 150 has a thickness within the above-described range, it may effectively draw the produced electrons from the semiconductor substrate 110 into the n+ region 130 side, effectively passivate the rear side of the semiconductor substrate 110, and back-reflect light having a relatively long wavelength, for example about 500 nm or more, in one embodiment, about 500 nm to about 1200 nm into the semiconductor substrate 110 so as to induce an increase of photoelectric current. Particularly, in one embodiment the first dielectric layer 150 may have a thickness of about 50 nm to about 100 nm.

The first dielectric layer 150 may also be used as a passivation layer for the rear side of the semiconductor substrate 110.

The second finger electrode 180c may be electrically connected under the p+ region 140. The second finger electrode 180c collects holes and may be formed of metal such as aluminum (Al) or other materials with similar characteristics, but is not limited thereto. When the second finger electrode 180c is formed of a paste including aluminum, the aluminum acts as a p-type impurity while contacting the aluminum with silicon of the semiconductor substrate 110, so a p+ region 140 is provided. Thereby the further step of providing a p+ region 140 may be omitted.

The second finger electrodes 180c are connected to each other through the second bus bar electrode 180d. The second bus bar electrode 180d may be formed of, for example, silver (Ag), aluminum (Al), or other materials with similar characteristics or a combination thereof.

The solar cell 100 may further include the second dielectric layer 160 positioned on the rear side of the semiconductor substrate 110 and disposed on the region where the first finger electrode 170c and the second finger electrode 180c are not provided, e.g., in regions between the second finger electrode 180c and an adjacent first finger electrode 170c. In one method of forming the second dielectric layer 160, the second dielectric layer may be formed across the entire rear surface of the solar cell 100 and may be removed at a position which overlaps with the first dielectric layer 150.

Although FIG. 2 shows that the second dielectric layer 160 is included, the embodiments of the solar cell 100 are not limited thereto, and the second dielectric layer 160 may be omitted.

The first dielectric layer 150 may have a fixed charge having a different electric characteristic from the second dielectric layer 160. For example, the first dielectric layer 150 may have a positive fixed charge, and the second dielectric layer 160 may have a negative fixed charge. In such an embodiment, the first dielectric layer 150 may have substantially the same structure as described above, and the second dielectric layer 160 is described hereinafter.

Since the second dielectric layer 160 has a negative fixed charge, it may draw the produced holes from the semiconductor substrate 110 to the rear side of the semiconductor substrate 110. The holes drawn to the rear side of the semiconductor substrate 110 may be pushed, i.e., electromagnetically repelled, from the first finger electrode 170c by the positive fixed charge of the first dielectric layer 150. Thereby, the first dielectric layer 150 may effectively collect holes into the second finger electrode 180c.

In addition, the second dielectric layer 160 having a negative fixed charge may have a larger surface area than the first dielectric layer 150 having a positive fixed charge. Thereby, it may easily draw holes, which have a slower transporting speed than electrons, into the rear side of the semiconductor substrate 110 and effectively collect them into the second finger electrode 180c.

The negative fixed charged material that may be included in the second dielectric layer 160 may include an oxide, a nitride, an oxynitride, or other materials having similar characteristics or a combination thereof having a predetermined composition, but is not limited thereto. For example, in one embodiment a nitride such as SiₓN_{y} may have a negative fixed charge by adjusting the ratio of x and y. Particularly, when x>y, the nitride may have a negative fixed charge. In the same way, the material such as AlₓO_{y}, SiₓO_{y}, SiₓO_{y}N_{z}, or the like may have a negative fixed charge by adjusting the ratio of x, y, and z. For example, in one embodiment the material having a negative fixed charge that may be included in the second dielectric layer 160 may include aluminum oxide (Al₂O₃), silicon oxide (SiO₂), silicon oxynitride (SiON), or other materials having similar characteristics or a combination thereof.

The second dielectric layer 160 may have a negative fixed charge density of about −1×10¹⁰ cm⁻² to about −1×10¹³ cm⁻². When the second dielectric layer 160 has a negative fixed charge density within the above-described range, it may easily draw the produced holes from the semiconductor substrate 110 into the p+ region 140 side, so as to effectively improve the efficiency of the solar cell 100.

In one embodiment, the second dielectric layer 160 may have a thickness of about 10 nm to about 200 nm. When the second dielectric layer 160 has a thickness within the above-described range, it may effectively draw the produced holes from the semiconductor substrate 110 to the rear side of semiconductor substrate 110, effectively passivate the rear side of semiconductor substrate 110, and back-reflect the light having a long wavelength, for example about 500 nm or more, in one embodiment, about 500 nm to about 1200 nm into the semiconductor substrate 110, so as to induce the increase of photoelectric current. For example, the second dielectric layer 160 may have a thickness of about 50 nm to about 100 nm.

The second dielectric layer 160 may also be used as a passivation layer for the rear side of the semiconductor substrate 110.

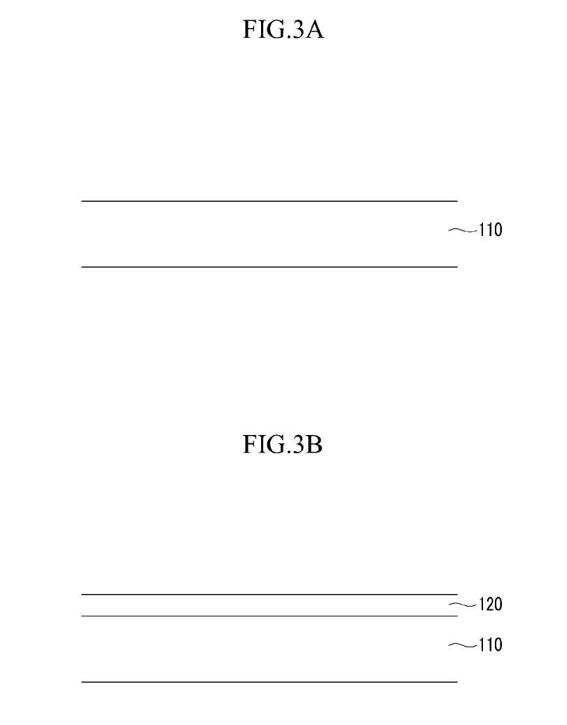

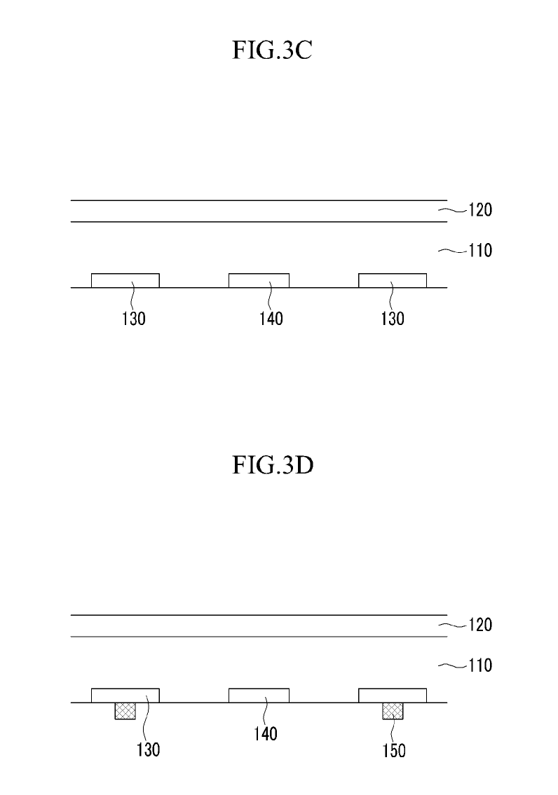

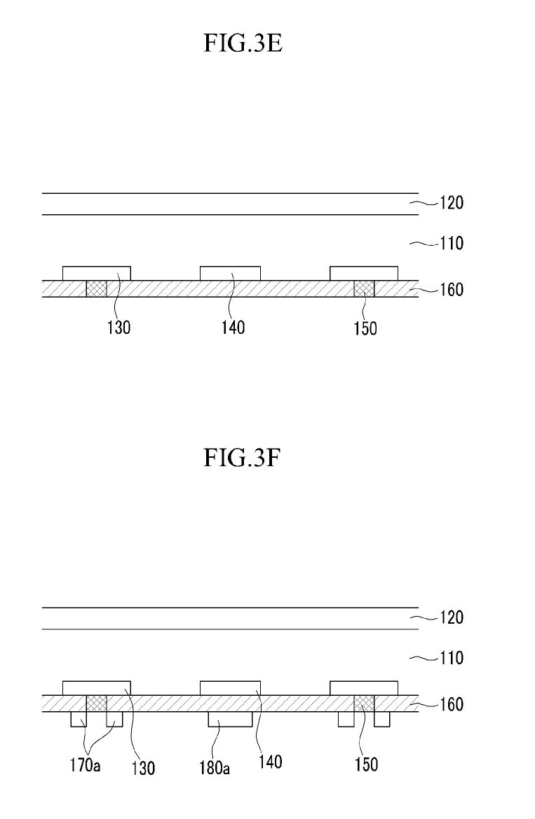

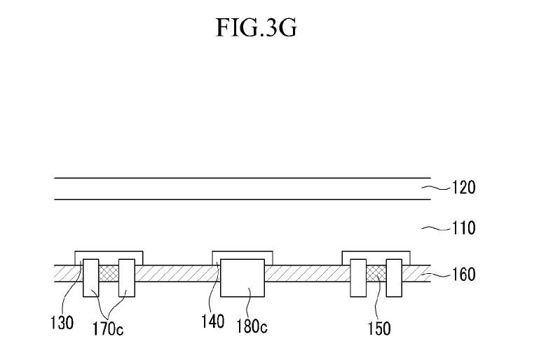

Hereinafter, an embodiment of a method of manufacturing an embodiment of a solar cell according to this disclosure is described with reference to FIGS. 3A to 3G along with FIGS. 1 and 2.

FIGS. 3A to 3G are cross-sectional views that sequentially show an embodiment of a process of manufacturing an embodiment of a solar cell.

Referring FIG. 3A, a semiconductor substrate 110 is provided. For example, in one embodiment a semiconductor substrate 110 such as a silicon wafer may be provided. The semiconductor layer 110 may be doped with a p-type impurity or an n-type impurity.

Then, according to one embodiment, the semiconductor layer 110 is subjected to a surface texturing treatment. The surface texturing treatment may be performed by a wet method using a strong acid such as nitric acid, hydrofluoric acid or other material with similar characteristics or strong base such as sodium hydroxide or other material with similar characteristics, or by a dry method using plasma. Embodiments also include configurations wherein the surface treatment is omitted.

Referring to FIG. 3B, an anti-reflection coating 120 is provided on the front surface of the semiconductor substrate 110. Although FIG. 3B shows the process of providing an anti-reflection coating 120, the present embodiment of a method is not limited thereto, and the process of providing an anti-reflection coating 120 may be omitted. Embodiments of the anti-reflection coating 120 may be formed by plasma enhanced chemical vapor deposition (“PECVD”) with, for example, silicon nitride. However, the method of forming the anti-reflection coating 120 is not limited thereto, and the anti-reflection coating 120 may be formed by other materials and methods.

As shown in FIG. 3C, an n+ region 130 and a p+ region 140 are disposed on a rear surface of the semiconductor substrate 110. The n+ region 130 and the p+ region 140 may be alternately disposed.

The n+ region 130 may be provided by doping a Group V element such as phosphorus (P) or other material with similar characteristics on the semiconductor substrate 110, and the p+ region 140 may be provided by doping a Group III element such as boron (B) or other material with similar characteristics on the semiconductor substrate 110. The doping may be performed by vapor diffusion, solid-phase diffusion, ion implantation, or other similar methods, but is not limited thereto. Although FIG. 3C shows that the p+ region 140 is separately provided, it is not limited thereto, and the providing the p+ region 140 may be omitted in an alternative embodiment wherein the p+ region 140 is formed while providing the second finger electrode 180c.

As shown in FIG. 3D, a first dielectric layer 150 is disposed under the n+ region 130 such that the first dielectric layer is vertically aligned with n+ region 130. The first dielectric layer 150 may be formed by providing a material having a positive fixed charge, for example, silicon nitride (Si₃N₄) or other material with similar characteristics, on the rear side of semiconductor substrate 110 in accordance with a PECVD process, and patterning the material having a positive fixed charge such that one part of the material having a positive fixed charge is disposed under, e.g., is vertically aligned with, the n+ region 130 in accordance with the dry etching using a photoresist. However, the method of formation of the first dielectric layer 150 is not limited thereto, and the first dielectric layer 150 may be formed by other materials and methods.

Referring to FIG. 3E, a second dielectric layer 160 is disposed on the region of the rear surface of the semiconductor substrate 110 where the first dielectric layer 150 is not positioned, i.e., on regions of the rear surface between adjacent first dielectric layers 150. Although FIG. 3E shows the process of providing a second dielectric layer 160, the method of forming the solar cell 100 is not limited thereto, and the process of providing a second dielectric layer 160 may be omitted. The second dielectric layer 160 may be obtained by providing a material having a negative fixed charge such as aluminum oxide (Al₂O₃) or other material with similar characteristics on the rear surface of the semiconductor substrate 110 in accordance with a PECVD process, and removing the negative fixed charged material at the position where it is overlapped with the first dielectric layer 150 under the first dielectric layer 150.

However, the method of forming the solar cell 100 is not limited thereto, and the second dielectric layer 160 may be obtained by other materials and methods.

In addition, although FIG. 3E does not show it, the second dielectric layer 160 may be provided without removing the negative fixed charged material at the position overlapping the first dielectric layer 150 under the first dielectric layer 150. In such an embodiment, the second dielectric layer 160 would overlap the first dielectric layer 150 in a region vertically aligned with the n+ region 130.

Referring to FIG. 3F, a conductive paste 170a for forming the plurality of first finger electrodes 170c is provided on one part under the second dielectric layer 160 adjacent to the first dielectric layer 150 at the overlapping region with the n+ region 130, and a conductive paste 180a for forming the second finger electrode 180c is provided under the second dielectric layer 160 at the overlapping region with the p+ region 140. In one embodiment, the conductive paste 170a for the first finger electrode and the conductive paste 180a for the second finger electrode may be formed by screen printing or other similar method. An embodiment of the screen printing includes coating a conductive paste for an electrode including a metal powder such as silver (Ag), aluminum (Al), or other material with similar characteristics on the position where the electrode is to be provided, and drying the same. However, the method of forming the finger electrodes 170c and 180c is not limited thereto, and it may be formed by inkjet printing, press printing, or other similar methods.

Then, as shown in FIG. 3G, the n+ region 130 is electrically connected to the plurality of first finger electrodes 170c, the plurality of first finger electrodes 170c electrically connected to the n+ region 130 and adjacent to each other are provided to be adjacent to both lateral sides of the first dielectric layer 150, and the second finger electrode 180c is provided to be electrically connected with the p+ region 140. The provided conductive paste 170a for the first finger electrode and the conductive paste 180a for the second finger electrode are baked to permeate the metal powder included in the conductive paste 170a for the first finger electrode and the conductive paste 180a for the second finger electrode into the n+ region 130 and the p+ region 140, respectively, of the semiconductor substrate 110 to provide the first finger electrode 170c and the second finger electrode 180c. The baking may be performed at a higher temperature than the fusion temperature of the metal powder, for example, in one embodiment the baking may be performed at a temperature of about 500° C. to about 1,000° C.

Although FIG. 3F and FIG. 3G show that the electrode is provided using the paste composition for the electrode, it is not limited thereto, and various methods may be applied in order to provide the electrode in the desirable position.

The embodiment of a solar cell 100 effectively collects electrons into the n-type electrode 170 and improves the efficiency of the solar cell 100 by disposing the first dielectric layer 150 having a positive fixed charge between the plurality of first finger electrodes 170c adjacent to each other and electrically connected to one n+ region.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A solar cell comprising:
a semiconductor substrate;
an n+ region disposed on a surface of the semiconductor substrate;
a plurality of first electrodes connected to the n+ region;
a p+ region disposed on the surface of the semiconductor substrate and separated from the n+ region;
a second electrode connected to the p+ region; and
a first dielectric layer which has a positive fixed charge and is disposed between adjacent first electrodes of the plurality of first electrodes.

2. The solar cell of claim 1, wherein the n+ region and the p+ region are alternately disposed with one another on the semiconductor substrate.

3. The solar cell of claim 1, wherein the first dielectric layer is selected from the group consisting of an oxide, a nitride, an oxynitride, and a combination thereof.

4. The solar cell of claim 1, wherein the first dielectric layer has a positive fixed charge density of about 1×10¹¹ cm⁻² to about 1×10¹³ cm⁻².

5. The solar cell of claim 1, wherein the first dielectric layer has a thickness of about 10 nm to about 200 nm.

6. The solar cell of claim 1, further comprising a second dielectric layer disposed on the surface of the semiconductor substrate in a region where the first electrode and the second electrode are omitted.

7. The solar cell of claim 6, wherein the second dielectric layer has a negative fixed charge.

8. The solar cell of claim 7, wherein the first dielectric layer has a positive fixed charge and is selected from the group consisting of an oxide, a nitride, an oxynitride and a combination thereof, and
wherein the second dielectric layer has a negative fixed charge and is selected from the group consisting of an oxide, a nitride, an oxynitride and a combination thereof.

9. The solar cell of claim 7, wherein the first dielectric layer has a positive fixed charge density of about 1×10¹¹ cm⁻² to about 1×10¹³ cm⁻².

10. The solar cell of claim 7, wherein the second dielectric layer has a negative fixed charge density of about −1×10¹⁰ cm⁻² to about −1×10¹³ cm⁻².

11. The solar cell of claim 7, wherein the second dielectric layer has a larger surface area than that of the first dielectric layer.

12. The solar cell of claim 6, wherein the first dielectric layer has a thickness of about 10 nm to about 200 nm.

13. The solar cell of claim 6, wherein the second dielectric layer has a thickness of about 10 nm to about 200 nm.

14. The solar cell of claim 6, wherein the second dielectric layer is removed from a position corresponding to an overlapping region with the first dielectric layer.

15. A method of manufacturing a solar cell, comprising:
providing a semiconductor substrate;
providing an n+ region on a surface of the semiconductor substrate;
providing a first dielectric layer at a position overlapping the n+ region;
providing a plurality of first electrodes connected to the n+ region; and
providing a p+ region separated from the n+ region; and
providing a second electrode connected to the p+ region on the surface of the semiconductor substrate,
wherein the first dielectric layer is positioned between adjacent first electrodes of the plurality of first electrodes.

16. The method of claim 15, wherein the n+ region and the p+ region are alternately provided.

17. The method of claim 15, further comprising providing a second dielectric layer on the surface of the semiconductor substrate after providing the first dielectric layer.

18. The method of claim 17, further comprising removing the second dielectric layer from a region overlapping with the first dielectric layer.
